(19) United States
(12) Patent Application Publication
(10) Pub. No.: US 2011/0318505 A1
(43) Pub. Date: Dec. 29, 2011

(54) METHOD FOR FORMING TANTALUM NITRIDE FILM AND FILM-FORMING APPARATUS FOR FORMING THE SAME

(76) Inventors: Akiko Yamamoto, Shizuoka (JP); Harunori Ushikawa, Shizuoka (JP); Nobuyuki Kato, Shizuoka (JP); Takakazu Yamada, Shizuoka (JP)

(21) Appl. No.: 13/130,997

(22) PCT Filed: Dec. 7, 2009
(86) PCT No.: PCT/JP2009/070482

§ 371 Date: Sep. 12, 2011

(30) Foreign Application Priority Data
Dec. 9, 2008 (JP) 2008-313692

(51) Int. Cl. C23C 16/34; C23C 16/455; C23C 16/448; C23C 16/50

(52) U.S. Cl. 427/569; 427/255.394; 118/723 R; 118/726

(57) ABSTRACT

A method for forming a tantalum nitride film, which comprises supplying a gaseous nitrogen atom-containing compound, as a reactant gas and supplying gaseous t-amylimido-tris-(dimethylamide)tantalum, as a gaseous raw material, to the surface of the substrate S to thus form a tantalum nitride film on the surface of the substrate S; and a film-forming apparatus, which comprises a reactant gas supply line L4; a container 13 for liquefy a raw material; an evaporator 11 for gasify the liquefied raw material; a liquid mass flow controller 12 for controlling the amount of the liquid raw material to be supplied; and a gaseous raw material supply line L1. These method and apparatus would permit the stable supply of the gaseous raw material at all times and the improvement of the throughput of the substrate to be processed and as a result, the method and the apparatus permit the improvement of the productivity of the tantalum nitride film.

### TECHNICAL FIELD

The present invention relates to a method for forming a tantalum nitride film and a film-forming apparatus for forming the same.

### BACKGROUND ART

In the progress of the semiconductor integrated circuits to the large-scale integrated circuits or in the advance thereof from LSI to ULSI, the wiring films or interconnection films used therein have correspondingly been required to reduce the width thereof to a level of its utmost limit. Recently, there have widely been used Cu films as such interconnection films for the semiconductor integrated circuits. In the process for forming a Cu interconnection film used in the high-tech devices on or after the development of 32 nm node, however, it would be quite difficult to fill holes and trenches with Cu according to the existing plating technique. This is because the barrier metal film required for the primary layer of the Cu interconnection film has presently been formed according to the PVD technique and the microfabrication thereof is quite difficult for the PVD technique and any satisfactory primary layer has not correspondingly been able to be prepared. For this reason, there has been desired for the development of a barrier metal film which shows high covering properties or coverage characteristics with respect to big holes and/or trenches each having a high aspect ratio and which likewise has an extremely low thickness and high barrier properties.

Under such circumstances, intense interest has recently been shown towards the atomic layer-deposition (hereunder referred to as “ALD”) technique which permits the deposition of a substance having a thickness, in fact, corresponding to several number of atoms or molecules (see, for instance, Patent Document 1 specified below). In this Patent Document 1, there has been disclosed a method for forming a metal-containing thin film according to the ALD technique.

The ALD technique is one which comprises the step of alternatively introducing a raw gas for forming a film and a reactant gas, in a pulsative manner, into the film-forming chamber of a vacuum apparatus to thus deposit, in layers, a thin film of an intended substance. Therefore, this technique can easily control the thickness of the resulting film by adjusting the repeated number of the pulses of the foregoing substances introduced into the film-forming chamber, the technique is likewise excellent in the step coverage characteristics and it would permit the formation of a thin film having a thickness distribution almost free of any scatter, as compared with the conventional thin film-forming techniques.

However, the ALD technique would suffer from such a problem that it is not favorable for the large-scale production of such films because of its quite slow film-forming rate.

On the other hand, there have been known, as barrier films for the copper distributing wires or the copper interconnections, a tantalum film because of its excellent adhesion to copper and its excellent diffusion barrier characteristics against copper; and a tantalum nitride film because of not only its excellent diffusion barrier characteristics against copper, like the tantalum film, but also the high ability thereof to be easily chemically polished due to its low hardness as compared with that of the tantalum film. In this respect, the halogenated tantalum compounds serving as raw materials for forming these films are ones each having a high melting point and a low vapor pressure. For this reason, problems would arise such that it is quite difficult to stably supply these raw materials to the film-forming chamber or apparatus, that the resulting tantalum film is contaminated with halogen atoms since the raw materials contain highly corrosive halogen atoms and that parts and/or members arranged within the film-forming chamber would undergo corrosion.

### PRIOR ART LITERATURE

### Patent Document

Patent Document 1: Japanese Un-Examined Patent Publication No. 2008-010888.

### SUMMARY OF THE INVENTION

### Problems that the Invention is to Solve

Accordingly, it is an object of the present invention to solve the foregoing problems associated with the conventional techniques and more particularly to provide a method for forming a tantalum nitride film which can ensure a high throughput of the substrate to be processed and the production of a tantalum nitride film having a good specific resistance, and which is characterized by the removal, from the film-forming process, of any halogen atom which may cause, for instance, the contamination of the resulting films; as well as a film-forming apparatus for forming the same.

### Means for the Solution of the Problems

A first invention relating to the method for forming a tantalum nitride film according to the present invention comprise the steps of supplying a nitrogen atom-containing compound in its gaseous state, as a reactant gas, on the surface of a substrate and supplying t-amylimide-tris(di-methylamide)tantalum in its gaseous state, as a raw gas, onto the surface of the substrate to thus form a tantalum nitride film on the substrate.

This first invention would permit the formation of a tantalum nitride film free of any contamination with a halogen atom, since the method uses a tantalum precursor free of any halogen atom as a raw gas.

A second invention relating to the method for forming a tantalum nitride film according to the present invention comprise the step of supplying t-amyl-imide-tris(dimethylamide)tantalum in its gaseous state, as a raw gas, in a pulsative manner, onto the surface of a substrate, while continuously supplying a nitrogen atom-containing compound in its gaseous state, as a reactant gas, onto the surface of the substrate to thus form a tantalum nitride film on the substrate.

A third invention relating to the method for forming a tantalum nitride film according to the present invention comprise the foregoing film-forming step, wherein the foregoing gaseous raw material used in the step is one prepared by heating t-amylimido-tris(dimethylamide)tantalum to a temperature ranging from 40 to 80° C. to thus liquefy the tantalum compound; and then further heating the resulting liquid tantalum compound in an evaporator to a temperature of not less than 100° C. and preferably 100 to 180° C. to thus gasify the liquid tantalum compound.

In the foregoing method, if the temperature for liquefying the starting tantalum compound is less than 40° C., the compound is not completely converted into its liquid state and this would interfere with the liquefaction of the raw material and/or the transportation of the liquefied raw material. On the other hand, if the temperature is higher than 80° C., the raw material would be exposed to a thermal stress over a long time period during the processes for liquefying the raw material and/or for transporting the resulting liquefied raw material and this may accordingly result in the thermal deterioration of the raw material. In addition, if the temperature for gasifying the liquid tantalum compound is less than 100° C., the gasification of the compound is incomplete, and this accordingly results in the spray to the substrate with a splash or droplet of the compound and the formation of a film showing a non-uniform thickness distribution. Moreover, if the temperature is too high, the raw gas is thermally decomposed to an undue extent and any intended film cannot be formed. Consequently, the upper limit of the gasifying temperature is preferably 180° C.

In the foregoing film-forming method, the raw material is initially supplied to the film-forming chamber in the form of a liquid and therefore, the amount of the raw material to be supplied thereto can accurately be controlled. Furthermore, an evaporator whose temperature is set at a predetermined level is used in the method and accordingly, the raw material in the form of a gas can always be supplied to the chamber in a stable and uniform amount as compared with the conventional bubbling method without being affected by the amount of the liquid raw material remaining in a container for accommodating the liquid raw material. This in turn permits not only the improvement of the productivity of the desired tantalum nitride film, but also the enhancement of the uniformity of the resulting films. As a result, the present invention, in particular, the foregoing second and third inventions would permit the preparation of a tantalum nitride film having a reduced specific resistance and more favorable characteristics as a barrier film within a considerably reduced period of time, as compared with the conventional ALD technique.

According to the foregoing film-forming method, it is also possible to more efficiently form a desired film, while improving the reactivity of the gas of a raw material through the use of a catalyst, or heat or a means for generating a plasma state of the raw material.

The method of the present invention is further characterized in that the foregoing gaseous nitrogen atom-containing compound is a gas selected from the group consisting of nitrogen gas, ammonia gas, hydrazine gas, and a gaseous hydrazine derivative.

A fourth aspect of the method for forming a tantalum nitride film according to the present invention comprises the steps of forming a tantalum nitride film on a substrate and then forming, on the tantalum nitride film thus formed, a film of a metal consisting of copper, tungsten, aluminum, tantalum, titanium, ruthenium, cobalt, nickel or an alloy thereof, wherein the tantalum nitride film is formed according to the foregoing film-forming technique by supplying, in the pulsative manner, t-amylimido-tris(dimethyl-amide)-tantalum in its gaseous form as a gaseous raw material, while supplying a gaseous nitrogen atom-containing compound as a reactant gas.

A fifth aspect of the method for forming a tantalum nitride film according to the present invention is characterized in that the method makes use of a catalyst, heat or plasma as a means for converting a reactant gas into its activated species; that a gaseous tantalum compound is supplied, in the pulsative manner, onto the surface of a substrate within a film-forming chamber, which is formed by heating t-amylimido-tris(dimethylamide)tantalum to a temperature ranging from 40 to 80° C. to thus liquefy the tantalum compound and then heating the resulting liquid tantalum compound in an evaporator to a temperature of not less than 100° C. to gasify the same, while supplying, as a reactant gas, a gas selected from the group consisting of nitrogen gas, ammonia gas, hydrazine gas, and a gaseous hydrazine derivative, to form a tantalum nitride film onto the surface of the substrate.

A sixth aspect of the present invention relating to a film-forming apparatus used for implementing the method for forming a tantalum nitride film likewise according to the present invention is one which comprises a vacuum processing chamber capable of forming a film in a gaseous phase while making use of a catalyst, heat or plasma and the apparatus comprises a reactant gas-supply line for supplying a reactant gas onto the surface of a substrate arranged within the vacuum processing chamber; a container for heating t-amylimido-tris(dimethylamide)tantalum, as a starting material for forming a gaseous raw material, at a temperature ranging from 40 to 80° C. to thus convert the compound into a liquid; an evaporator for heating the liquefied t-amylimido-tris(dimethylamide)tantalum at a temperature of not less than 100° C., preferably ranging from 100 to 180° C. to gasify the liquid compound; a liquid mass flow controller for controlling the amount of the liquid tantalum compound to be supplied to the evaporator; and a gaseous raw material supply line for supplying the gas produced in the evaporator to the surface of the substrate placed within the vacuum processing chamber.

The film-forming apparatus of the present invention is further characterized in that the evaporator is directly connected to the vacuum processing chamber.

The film-forming apparatus of the present invention is further characterized in that the reactant gas supply line is provided with a catalyst wire for converting the reactant gas into activated species and that it also equipped with a heating mechanism for heating the catalyst.

### EFFECTS OF THE INVENTION

The present invention shows the following effects: The film-forming method according to the present invention permits the formation of a tantalum nitride film by supplying, to a film-forming chamber, the gaseous t-amylimido-tris(dimethyl-amide)tantalum which is obtained by gasifying a raw material thereof in an evaporator, in the pulsative manner, while at the same time, continuously supplying a reactant gas to the film-forming chamber. Thus, the method permits the achievement of an improved film-forming rate and an improved throughput as compared with the conventional film-forming techniques and the resulting tantalum nitride film has a low specific resistance.

### BRIEF DESCRIPTION OF DRAWINGS

FIG. 1 is a schematic block diagram illustrating an embodiment of the construction of a film-forming apparatus used for forming a tantalum nitride film according to the present invention.

FIG. 2 is a flow chart illustrating the tantalum nitride film-forming processes used in Example 1.

FIG. 3 is a graph showing the influence of the temperature (° C.) used for forming a tantalum nitride film on the film-forming rate (nm/cycle) and the specific resistance (μΩcm) of the resulting film.

FIG. 4 is a flow chart illustrating the tantalum nitride film-forming processes used in Comparative Example 1.

### MODE FOR CARRYING OUT THE INVENTION

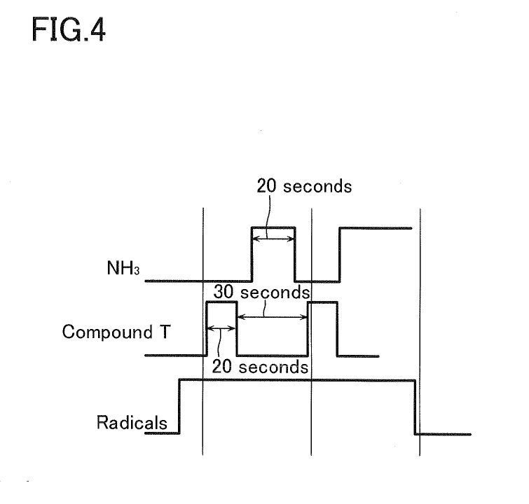

According to a mode for carrying out the method for forming a tantalum nitride film according to the present invention, a tantalum nitride film can be prepared by supplying, onto the surface of a substrate, a gas, as a reactant gas, selected from the group consisting of nitrogen gas, ammonia gas, hydrazine gas, and a gaseous hydrazine derivative; and, at the same time, supplying, on the surface of the substrate, a gaseous raw material, in the pulsative manner, which is prepared by heating t-amylimido-tris(dimethyl-amide)tantalum (hereunder referred to as “compound T”) to a temperature ranging from 40 to 80° C. to liquefy the compound T and then further heating the liquefied compound T at a temperature ranging from 100 to 180° C. in an evaporator to thus gasify the same, while using a method which makes use of a catalyst, heat or plasma as a means for converting the reactant gas into activated species. In this connection, the use of a gasification temperature of higher than 180° C. would result in not only the cleavage of the double bond present in the compound T, but also the progress of other thermal decomposition of the compound T and accordingly, any desired tantalum nitride film cannot be produced (see FIG. 4 attached to the gazetted specification of Japanese Patent No. 3,963,078).

The film-forming method which makes use of a catalyst, heat or plasma used in the present invention is one in which a film is formed by periodically supplying, on the surface of a substrate, a gaseous raw material for a predetermined time period as pulses, while continuously supplying a reactant gas to thus induce the reaction between them and to thus form a desired film.

For instance, this method comprises the step of repeating, over predetermined times, the cycle which comprises supplying a predetermined amount of the compound T as a gaseous raw material to a vacuum processing chamber of a film-forming apparatus for a desired period of time (for instance, 0.1 to 300 seconds, preferably about 0.1 to about 30 seconds) and then suspending the supply thereof to the chamber for a predetermined time period (for instance, 0.1 to 300 seconds, preferably about 0.1 to about 60 seconds), or supplying, in a pulsative manner, the compound T, while continuously supplying a predetermined amount of a reactant gas such as ammonia gas to the vacuum processing chamber; and then terminating the supply of the gaseous raw material and the reactant gas to thus give a tantalum nitride film having a desired film thickness. In this respect, the tantalum nitride film is formed through the reaction between the gaseous raw material and the reactant gas.

In the film-forming method in which a reactant gas is converted into activated species through the action of a catalyst, the reactant gas is brought into close contact with a catalyst wire resistively-heated to a high temperature (for instance, a temperature ranging from 1700 to 2500° C.) by passing an electric current through the wire to thus decompose and activate the reactant gas by the action of the catalyst and to thus form activated species in the form of radicals; and the resulting activated species thus formed are reacted with the gaseous raw material to form a tantalum nitride film having a desired film thickness. In this film-forming method which makes use of such a catalytic action, the temperature of the substrate is set at a level ranging from 200 to 400° C. In this case, the gaseous raw material is brought into contact with the catalyst wire maintained at a high temperature when converting the reactant gas into activated species, the carbon atoms present in the gaseous raw material are correspondingly decomposed. Accordingly, any contamination of the resulting film can be prevented and the method thus permits the formation of a film having a low specific resistance. Alternatively, in the film-forming methods in which the reactant gas is converted into activated species through the use of heat or plasma, the temperature of the substrate is set at a level ranging from 150 to 700° C. In this case, the substrate is heated by a heating means such as a heater and the cycle described above is repeated over predetermined times to thus form, on the substrate, a tantalum nitride film having a desired film thickness.

Examples of the foregoing hydrazine derivatives used as reactant gases include methyl hydrazine and dimethyl hydrazine and the like.

After forming such a tantalum nitride film as a metal barrier film, a film of a metal selected from the group consisting of copper, tungsten, aluminum, tantalum, titanium, ruthenium, cobalt, nickel and an alloy thereof is formed on the metal barrier film, according to, for instance, the CVD technique under the known process conditions. In this case, there is sometimes observed the deterioration of the adhesion between the metal film thus formed and the tantalum nitride film. The problem of this deterioration of the adhesion between them can be solved by subjecting the tantalum nitride film to an appropriate post-treatment after the preparation thereof, for instance, by the formation of an another metal nitride film on the surface of the tantalum nitride film or by allowing nitrogen gas to be adsorbed on the surface of the tantalum nitride film and then subjecting the metal nitride film or the tantalum nitride film carrying nitrogen molecules adsorbed thereon to an annealing treatment to thus ensure the strict adhesion between them. In other words, the metal nitride film formed on or a layer of nitrogen molecules adsorbed on the surface of the tantalum nitride film would certainly occupy the active metal-adsorptive sites present on or in the tantalum nitride film and this accordingly suppresses the formation of any layer of the reaction products of tantalum nitride with impurities such as oxygen, fluorine atom-containing compounds, water and ammonia (for instance, interfacial layer of, for instance, metal oxides, if the impurities are composed of oxygen molecules). Accordingly, it would be believed that the mutual diffusion with Ta and Cu may easily occur even if the annealing treatment is carried out at a low temperature and that the adhesion between them can thus be improved.

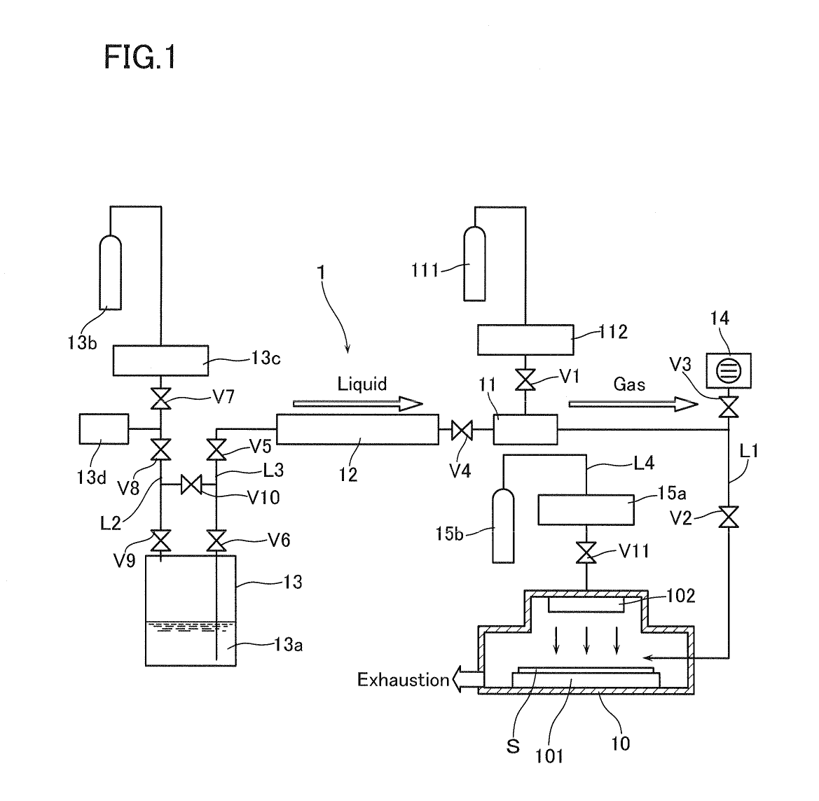

The film-forming apparatus according to the present invention, which permits the implementation of the method for forming a tantalum nitride film, is not restricted to any particular one and an example thereof may be a film-forming apparatus as shown in FIG. 1.

The film-forming apparatus 1 consists of a vacuum processing chamber 10 for forming a tantalum nitride film on a substrate S which is transported to the chamber through a substrate-housing (not shown); an evaporator 11; a liquid mass flow controller 12; and a container 13 for accommodating a source 13a of a liquid raw material (the compound T) used for forming a gaseous raw material.

The film-forming apparatus is so designed that the vacuum processing chamber 10 is provided with an exhaust means (not shown) such as a turbo-molecular pump. A bomb 111 charged with a carrier gas, for instance, an inert gas (such as Ar) is connected, through a valve V1 and a mass flow controller 112, to the evaporator 11 which is in turn connected to the vacuum processing chamber 10 through a line L1 for supplying a gaseous raw material, in such a manner that the gaseous raw material supplied through the evaporator 11 can be introduced into the vacuum processing chamber 10 together with the carrier gas. A valve V2 is provided in the line L1 on the side of the vacuum processing chamber 10 and a vacuum pump 14 is connected, through a valve V3, to the line L1 on the side of the evaporator 11. The film-forming apparatus is likewise so designed that the liquid raw material contained in the source 13a thereof is transported towards the evaporator 11 by the action of a pressure application means as will be detailed below and the gaseous raw material formed within the evaporator 11 can thus be introduced into the vacuum processing chamber 10.

The evaporator 11 is connected to the liquid mass flow controller 12 through a valve V4, while the liquid mass flow controller 12 is connected to the container 13 through valves V5 and V6 or a line L3. The container 13 is provided with a pressure application means and the latter serves to supply the liquid raw material contained in the source 13a thereof to the evaporator 11 through the liquid mass flow controller 12, when it is operated. The pressure application means is one which serves to apply a pressure to the source 13a and to thus make the liquid raw material present therein enter into the evaporator 11. Accordingly, it is composed of a gas bomb 13b charged with an inert gas (such as helium gas) and a mass flow controller 13c and is connected to the container 13 through a line L2. This line L2 is provided with valves V7, V8 and V9, which are arranged in this order from the side of the mass flow controller 13c towards the container 13 and a pressure gauge 13d for the observation of the pressure of the inert gas is provided between the valves V7 and V8. Moreover, the lines L2 and L3 are interconnected at the points each positioned between the valves V5 and V6 or between the valves V8 and V9, through a valve V10. If the valve 10 is opened while the valves V6 and V9 are closed, the atmosphere which has been passed through the lines L2 and L3 can be exhausted and this can, accordingly, prevent any clogging of the piping due to the solidification of the raw material through the reaction thereof with the atmosphere, even if any liquid raw material, the vapor thereof and/or the gaseous raw material flow into the lines L2 and L3 through the source 13a of the liquid raw material, when the valves V6 and V9 are opened.

The piping work, through which the compound T in the liquid state passes or which extends from the container 13 to the liquid mass flow controller 12, is kept warm at a temperature ranging from 40 to 80° C. and the compound T in the liquid state is transported towards the evaporator 11 by the action of the pressure of He. The evaporation temperature of the evaporator 11 is set at a level of not less than 100° C. The compound T converted into its gaseous state in the evaporator is supplied onto the surface of the substrate S positioned within the vacuum processing chamber 10. A heater (not shown) for heating the substrate S is so designed that the heating temperature thereof can be set at a level ranging from 150 to 700° C.

A substrate stage 101 for placing the substrate S is provided within the vacuum processing chamber 10 and when using the catalytic CVD technique, a catalyst wire 102 is disposed at an upper portion of the vacuum processing chamber 10, while the catalyst wire and the substrate stage 101 are, in this case, opposed to one another.

In this catalytic CVD technique, the film-forming apparatus is so designed that the reactant gas such as NH₃, N₂ or H₂ and the carrier gas such as Ar or N₂ are introduced into the vacuum processing chamber 10 at an upper portion of the catalyst wire 102 through each corresponding gas bomb 15a and mass flow controller 15b, respectively, that they are then brought into close contact with the catalyst wire heated to a temperature ranging from 1700 to 2500° C. and decomposed into radicals thereof and activated due to the catalytic action of the catalyst, and that the resulting activated species thus obtained and having high reactivity are supplied onto the surface of the substrate S, on which they undergo a reaction with the gaseous raw material to thus form a metal film (a tantalum nitride film). A valve V11 is provided in a line L4 for the introduction of the reactant gas into the vacuum processing chamber on the side of the vacuum processing chamber.

In the film-forming apparatus 1 as shown in FIG. 1, as has been described above, the compound T in its liquid state or the source 13a of the liquid raw material which is accommodated in the container 13 and heated to a temperature ranging from 40 to 80° C. is transported, at a predetermined flow rate, to the evaporator 11 through the liquid mass flow controller 12, the compound T in its liquid state is then heated to a temperature of not less than 150° C. in the evaporator 11, the compound T converted into a gaseous state is introduced into the vacuum processing chamber 10, in a pulsative manner, and supplied onto the surface of the substrate S placed within the chamber, while a reactant gas is introduced into and guided towards the catalyst wire 102 through the upper portion of the vacuum processing chamber 10, and the activated species of the reactant gas formed by the action of the catalyst wire 102 is likewise supplied onto the surface of the substrate S on which the compound T reacts with the activated species to thus give a desired film on the substrate S.

### Example 1

In this Example, a tantalum nitride film was formed using the film-forming apparatus as shown in FIG. 1.

More specifically, an Si substrate was used as a substrate to be processed; this substrate was placed on the substrate stage within the vacuum processing chamber; the substrate was then heated to 300° C.; NH₃ as a reactant gas was continuously introduced into the processing chamber and guided towards the catalyst wire heated to a predetermined temperature ranging from 1700 to 2500° C. through the upper portion of the vacuum processing chamber at a flow rate of 400 sccm so that the reactant gas was brought into close contact with the catalyst wire to thus allow the catalyst wire to generate activated species of the reactant gas such as radicals thereof; the resulting activated species were then supplied onto the surface of the substrate, while the gas of the compound T as a gaseous raw material was introduced, simultaneous with the introduction of NH₃ as the reactant gas, into the processing chamber and supplied onto the surface of the substrate at a rate of 0.1 g/min as expressed in terms of the weight of the compound T in its solid state for 25 seconds so that the gaseous raw material underwent a reaction with the activated species of the reactant gas on the substrate to thus form a tantalum nitride film thereon; then the introduction of the compound T in the gaseous state was interrupted and this state was maintained for 60 seconds. In this respect, the compound T in its gaseous state was introduced into the vacuum processing chamber through the evaporator whose temperature was set at 150° C.

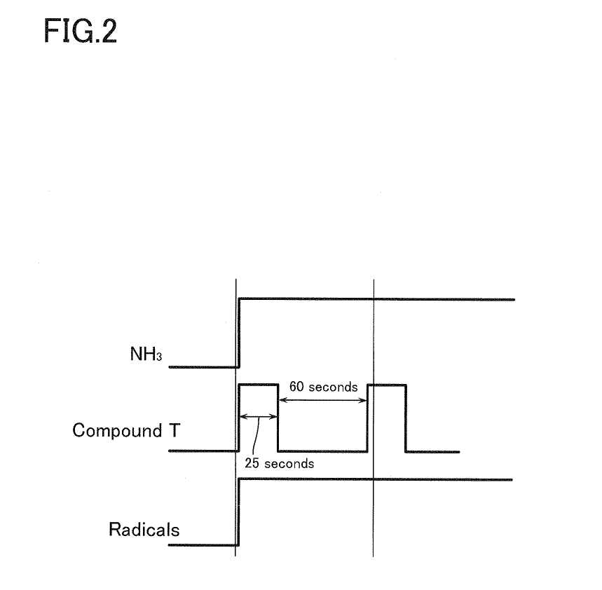

Then the introduction of the compound T and the stopping of the supply thereof were repeated under the same conditions described above over 12 cycles, while keeping the introduction of the reactant gas into the vacuum processing chamber to thus form an intended tantalum nitride film. FIG. 2 shows the flow chart of this film-forming process.

The tantalum nitride film thus produced was found to have a film thickness of 9.0 nm. In the foregoing film-forming process, the film-forming rate was found to be 0.52 nm/min and the film thickness per one cycle was found to be 0.76 nm. In addition, the resulting film was found to have a specific resistance of 2200 μΩcm and the throughput of the foregoing process was found to be 12 substrates/hour.

### Example 2

In this Example, there were examined the influence of the film-forming temperature on the film-forming rate (nm/cycle) and the specific resistance (μΩcm) of the resulting film.

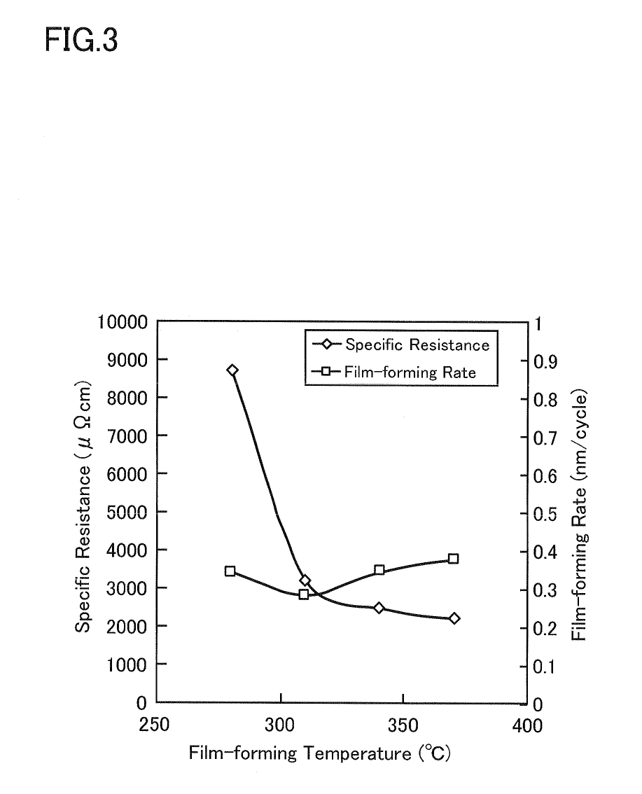

The same film-forming process used in Example 1 was repeated except that the temperature of the substrate was set at a level ranging from 280 to 370° C. and the film-forming process was repeated over 32 cycles. The results thus obtained are plotted on the attached FIG. 3.

As will be clear from the data plotted on FIG. 3, the tantalum nitride films produced at a substrate temperature (film-forming temperature) ranging from 310 to 370° C. were found to have a low specific resistance and the film-forming rate was found to be high when setting the substrate temperature at a level ranging from 270 to 370° C.

### Example 3

In this Example, the gaseous raw material and the reactant gas were simultaneously introduced into the film-forming apparatus, unlike Examples 1 and 2, for the production of a tantalum nitride film.

More specifically, an Si substrate was used as a substrate to be processed; this substrate was placed on the substrate stage within the vacuum processing chamber; the substrate was then heated to a temperature of 300° C.; the gas of the compound T as a gaseous raw material was introduced into the vacuum processing chamber and supplied, onto the surface of the substrate, at a flow rate of 0.10 g/min as expressed in terms of the weight of the compound T in its solid state for 60 seconds so that the compound T in its gaseous state was adsorbed on the substrate and decomposed on the same. The gaseous compound T introduced into the chamber was a gas obtained by passing the same through the evaporator whose temperature was set at 150° C. At the same time, NH₃ as a reactant gas was introduced into the vacuum processing chamber and guided towards the catalyst wire heated to a predetermined temperature ranging from 1700 to 2500° C. and positioned within the vacuum processing chamber at a flow rate of 400 sccm for 60 seconds so that the reactant gas was converted into activated species such as radicals thereof by the action of the catalyst wire; and then the activated species were supplied onto the surface of the substrate to thus form an intended tantalum nitride film.

The tantalum nitride film thus prepared was found to have a film thickness of 10 nm. In this process, the film-forming rate was found to be 10 nm/min. As compared with Example 1, the film-forming rate was high, but the resulting film was found to have a rather high specific resistance on the order of 10,000 μΩcm and the throughput of the process was found to be quite high on the order of 15 substrates/hour.

### Example 4

In this Example, the gaseous raw material and the reactant gas were simultaneously introduced into the vacuum processing chamber without heating the catalyst wire to thus form a tantalum nitride film.

More specifically, an Si substrate was used as a substrate to be processed; this substrate was placed on the substrate stage within the vacuum processing chamber; the substrate was then heated to a temperature of 300° C.; the gas of the compound T as a gaseous raw material was introduced into the vacuum processing chamber and supplied, onto the surface of the substrate, at a flow rate of 0.10 g/min as expressed in terms of the weight of the compound T in its solid state for 60 seconds so that the compound T in its gaseous state was adsorbed on the substrate and decomposed on the same. The gaseous compound T introduced into the chamber was a gas obtained by passing the same through the evaporator whose temperature was set at 150° C. At the same time, NH₃ as a reactant gas was introduced into the vacuum processing chamber at a flow rate of 400 sccm for 60 seconds so that the reactant gas was converted into activated species; and then the resulting activated species were supplied onto the surface of the substrate to thus form an intended tantalum nitride film.

The tantalum nitride film thus prepared was found to have a film thickness of 10 nm. In this process, the film-forming rate was found to be 10 nm/min. As compared with Example 1, the film-forming rate was high, but the resulting film was found to have a rather high specific resistance on the order of 12,000 μΩcm and the throughput of the process was found to be quite high on the order of 13 substrates/hour.

### Comparative Example 1

In this Comparative Example, a tantalum nitride film was produced according to the ALD technique and the resulting tantalum nitride film was compared with that produced in Example 1.

More specifically, an Si substrate was used as a substrate to be processed; this substrate was placed on the substrate stage within the vacuum processing chamber; the substrate was then heated to a temperature of 300° C.; the gas of the compound T as a gaseous raw material was introduced into the vacuum processing chamber and supplied, onto the surface of the substrate, at a flow rate of 0.15 g/min as expressed in terms of the weight of the compound T in its solid state for 20 seconds so that the compound T in its gaseous state was adsorbed on the substrate and decomposed on the same; and thereafter, the gaseous raw material remaining in the vacuum processing chamber was purged for 5 seconds, while using Ar gas as a purge gas. The gaseous compound T introduced into the chamber was a gas obtained by passing the same through the evaporator whose temperature was set at 150° C. Then, NH₃ as a reactant gas is introduced into the vacuum processing chamber and guided towards the catalyst wire provided therein and heated to a temperature ranging from 1700 to 2500° C. at a flow rate of 400 sccm for 20 seconds so that the reactant gas was converted into activated species such as radicals thereof by the action of the catalyst wire; and then the activated species were supplied onto the surface of the substrate. At this stage, a reaction took place on the substrate and as a result, a tantalum nitride film was formed thereon.

Then the reactant gas remaining in the vacuum processing chamber was purged for 5 seconds using an Ar gas as a purge gas, and the cycle comprising the supply of the gaseous compound T and the supply of NH₃ as the reactant gas was repeated under the same conditions used above over 270 times (or cycles) to thus form an intended tantalum nitride film. FIG. 4 shows the flow chart of this film-forming process.

The tantalum nitride film thus produced was found to have a film thickness of 8.9 nm. In the foregoing film-forming process, the film-forming rate was found to be 0.040 nm/min and the film thickness per cycle was found to be 0.033 nm. As compared with the results obtained in Example 1, the film-forming rate of this process was found to be low and as a result, the film thickness per cycle was found to be small. Moreover, the resulting film was found to have a specific resistance on the order of 4800 μΩcm and the throughput of the foregoing process was found to be quite low on the order of 2 substrates/hour, as compared with Example 1.

### INDUSTRIAL APPLICABILITY

According to the method for forming a tantalum nitride film of the present invention, the gaseous raw material can always stably be supplied to the film-forming apparatus, the uniformity of the film thickness can be improved and the throughput of the substrates to be processed can likewise be enhanced. As a result, the method of the present invention would permit the improvement of the productivity. Accordingly, the method according to the present invention can effectively be used in the technical fields which make use of tantalum nitride films, for instance, in the field of semiconductor devices which require the formation of, for instance, a metal barrier layer for Cu distributing wires or interconnections.

### EXPLANATION OF THE SYMBOLS

1 . . . Film-forming apparatus; 10 . . . Vacuum processing chamber; 11 . . . Evaporator; 12 . . . Liquid mass flow controller; 13 . . . Container; 13a . . . Source of liquid raw material; 13b . . . Gas bomb; 13c . . . Mass flow controller; 13d . . . Pressure gauge; 14 . . . Vacuum pump; 15a . . . Gas bomb; 15b . . . Mass flow controller; 101 . . . Substrate stage; 102 . . . Catalyst wire; 111 . . . Gas-charged bomb; L1 to L4 . . . Lines; V1 to V10 . . . Valves; S . . . Substrate.

1-10. (canceled)

11. A method for forming a tantalum nitride film comprising the steps of supplying a gas of a nitrogen atom-containing compound, as a reactant gas, onto the surface of a substrate; and supplying gasified t-amylimido-tris(dimethylamide)tantalum, as a gaseous raw material, which is obtained by heating t-amylimido-tris-(dimethylamide)tantalum at a temperature ranging from 40 to 80° C. to liquefy the tantalum compound and then heating the resulting liquid in an evaporator at a temperature of not less than 100° C. to gasify the liquid, to thus form a tantalum nitride film on the substrate.

12. A method for forming a tantalum nitride film comprising the step of supplying, in a pulsative manner, gasified t-amylimido-tris(dimethylamide)tantalum, as a gaseous raw material, on the surface of a substrate, which is obtained by heating t-amylimido-tris(dimethylamide)tantalum to a temperature ranging from 40 to 80° C. to liquefy the tantalum compound and then heating the resulting liquid in an evaporator to a temperature of not less than 100° C. to gasify the liquid, while supplying a gas of a nitrogen atom-containing compound, as a reactant gas, onto the surface of the substrate, to form a tantalum nitride film on the substrate.

13. The method for forming a tantalum nitride film as set forth in claim 11, wherein the method for forming the tantalum nitride film makes use of a catalyst, heat or plasma.

14. The method for forming a tantalum nitride film as set forth in claim 12, wherein the method for forming the tantalum nitride film makes use of a catalyst, heat or plasma.

15. The method for forming a tantalum nitride film as set forth in claim 11, wherein the gas of the nitrogen atom-containing compound is one selected from the group consisting of nitrogen gas, ammonia gas, hydrazine gas, and a gaseous hydrazine derivative.

16. The method for forming a tantalum nitride film as set forth in claim 12, wherein the gas of the nitrogen atom-containing compound is one selected from the group consisting of nitrogen gas, ammonia gas, hydrazine gas, and a gaseous hydrazine derivative.

17. The method for forming a tantalum nitride film as set forth in claim 13, wherein the gas of the nitrogen atom-containing compound is one selected from the group consisting of nitrogen gas, ammonia gas, hydrazine gas, and a gaseous hydrazine derivative.

18. The method for forming a tantalum nitride film as set forth in claim 14, wherein the gas of the nitrogen atom-containing compound is one selected from the group consisting of nitrogen gas, ammonia gas, hydrazine gas, and a gaseous hydrazine derivative.

19. A method for forming a tantalum nitride film which comprises forming a tantalum nitride film on the surface of a substrate and then forming, on the tantalum nitride film, a film of a metal selected from the group consisting of copper, tungsten, aluminum, tantalum, titanium, ruthenium, cobalt, nickel and alloys thereof, wherein the tantalum nitride film is formed by supplying, onto the surface of the substrate, gasified t-amylimido-tris (dimethylamide)tantalum as a gaseous raw material, in a pulsative manner, which is obtained by heating t-amylimido-tris(dimethyl-amide)tantalum to a temperature ranging from 40 to 80° C. to liquefy the tantalum compound and then heating the resulting liquid in an evaporator to a temperature of not less than 100° C. to gasify the liquid, while supplying a gaseous nitrogen atom-containing compound, as a reactant gas, onto the surface of the substrate.

20. A method for forming a tantalum nitride film characterized in that a catalyst, heat or plasma is used as a means for converting a reactant gas into activated species and that a tantalum nitride film is formed on the surface of a substrate by supplying, in a pulsative manner, a gaseous raw material, onto the surface of a substrate, which is prepared by heating t-amylimido-tris(dimethyl-amide)tantalum to a temperature ranging from 40 to 80° C. to liquefy the tantalum compound and then heating the resulting liquid in an evaporator to a temperature of not less than 100° C. to gasify the liquid, while supplying a gas, as the reactant gas, selected from the group consisting of nitrogen gas, ammonia gas, hydrazine gas, and a gaseous hydrazine derivative, onto the surface of the substrate.

21. A film-forming apparatus equipped with a vacuum processing chamber which permits the formation of a film in a gas phase, while making use of a catalyst, heat or plasma, wherein the apparatus comprises a reactant gas supply line for supplying a reactant gas onto the surface of a substrate positioned within the vacuum processing chamber; a container for heating t-amylimido-tris(dimethylamide)tantalum used for forming a gaseous raw material to a temperature ranging from 40 to 80° C. to liquefy the tantalum compound; an evaporator for heating the liquefied t-amylimido-tris (dimethylamide)tantalum to a temperature of not less than 100° C. to gasify the liquid; a liquid mass flow controller for adjusting the amount of the liquid tantalum compound to be supplied to the evaporator; and a gaseous raw material supply line for supplying the gas formed in the evaporator to the surface of the substrate positioned within the vacuum processing chamber.

22. The film-forming apparatus as set forth in claim 21, wherein the evaporator is further directly connected to the vacuum processing chamber.

23. The film-forming apparatus as set forth in claim 21, wherein the apparatus is further provided with a catalyst wire for converting the reactant gas into activated species, which is disposed on the reactant gas supply line.

24. The film-forming apparatus as set forth in claim 22, wherein the apparatus is further provided with a catalyst wire for converting the reactant gas into activated species, which is disposed on the reactant gas supply line.

25. The film-forming apparatus as set forth in claim 23, wherein the apparatus is further provided with a heating mechanism for heating the catalyst wire.

26. The film-forming apparatus as set forth in claim 24, wherein the apparatus is further provided with a heating mechanism for heating the catalyst wire.
